(19) United States
(12) Patent Application Publication
(10) Pub. No.: US 2021/0249483 A1
(43) Pub. Date: Aug. 12, 2021

(54) PIXEL ARRANGEMENT STRUCTURE, DISPLAY PANEL AND DISPLAY DEVICE

(71) Applicant: KunShan Go-Visionox Opto-Electronics Co., Ltd., Kunshan (CN)

(72) Inventor: Jinku Li, Kunshan (CN)

(21) Appl. No.: 17/211,016

(22) Filed: Mar. 24, 2021

Related U.S. Application Data
(63) Continuation of application No. PCT/CN2020/075465, filed on Feb. 17, 2020.

(30) Foreign Application Priority Data
Feb. 27, 2019 (CN) 201910147357.5

(51) Int. Cl. H01L 27/32

(52) U.S. Cl. CPC H01L 27/3218; H01L 27/3216

(57) ABSTRACT

A pixel arrangement structure, a display panel and a display device are provided in the present application. The pixel arrangement structure includes a plurality of pixel groups, each pixel group includes a first color light sub-pixel, a plurality of second color light sub-pixels and a plurality of third color light sub-pixels. The plurality of second color light sub-pixels and the plurality of third color light sub-pixels are alternately arranged around the first color light sub-pixel. Two adjacent pixel groups share a second color light sub-pixel and a third color light sub-pixel located between the two adjacent pixel groups.

### CROSS-REFERENCE TO RELATED APPLICATIONS

The present application is a continuation of International Application No. PCT/CN2020/075465 filed on Feb. 17, 2020, which claims priority to Chinese patent application No. 201910147357.5 filed on Feb. 27, 2019. Both applications are incorporated herein by reference in their entireties.

### TECHNICAL FIELD

The present application relates to a technical field of flat panel display, in particular to a pixel arrangement structure, a display panel and a display device.

### BACKGROUND

Organic Light-Emitting Diode (OLED) displays have advantages of active emission, light and thin, large viewing angle, fast response speed, energy saving, wide temperature tolerance range, flexible display and transparent display, and the like, and are regarded as the most promising new flat panel display technology for the next generation.

In the prior art, an OLED full colorization method with the best effect is a pixel side-by-side method, that is, three sub-pixel units of red (R), green (G) and blue (B) are disposed side-by-side into a pixel unit to serve as three primary color pixels, and each of the three sub-pixel units includes an independent organic light-emitting device. By adjusting a color mixing ratio of a combination of three colors, a true multicolor is produced, so that RGB three-color organic light-emitting devices independently emit light and constitute one pixel.

However, in the OLED display, a lifetime of a blue light device, especially a deep blue light device, is much shorter than that of a red light device and a green light device. Therefore, when using the OLED display, due to a decline of the blue light device, a display picture may be yellowed, thereby greatly shortening an effective service life of the entire display.

### SUMMARY

The present application provides a pixel arrangement structure, a display panel, and a display device to improve a problem that the effective service life of the entire display is greatly shortened due to the decline of the blue light device existing in the prior art.

In a first aspect, a pixel arrangement structure provided according to embodiments of the present application includes: a plurality of pixel groups, wherein each of the plurality of pixel groups comprises a first color light sub-pixel, a plurality of second color light sub-pixels and a plurality of third color light sub-pixels, and the plurality of second color light sub-pixels and the plurality of third color light sub-pixels are alternately arranged around the first color light sub-pixel; wherein the plurality of pixel groups are arranged in at least two rows and/or at least two columns, and two adjacent pixel groups of the plurality of pixel groups share a second color light sub-pixel and a third color light sub-pixel located between the two adjacent pixel groups.

In a second aspect, a display panel provided according to embodiments of the present application includes the pixel arrangement structure above described.

In a third aspect, a display device provided according to embodiments of the present application includes the display panel above described.

According to the technical solutions of the present application, a pixel arrangement structure including a plurality of pixel groups is constructed, wherein each of the plurality of pixel groups comprises a first color light sub-pixel, a plurality of second color light sub-pixels and a plurality of third color light sub-pixels, and the plurality of second color light sub-pixels and the plurality of third color light sub-pixels are alternately arranged around the first color light sub-pixel. This surrounding mode of the technical solutions relatively increases an aperture ratio of the first color light sub-pixel, and slows down an attenuation of the first color light sub-pixel. In the technical solutions, the plurality of second color light sub-pixels and the plurality of third color light sub-pixels share one first color light sub-pixel, and each second color light sub-pixel and each third color light sub-pixel are shared by two adjacent pixel groups. This sharing method of the technical solutions can effectively improve a pixel resolution. In addition, even if some of the first color light sub-pixels are attenuated or damaged, the use of the second color light sub-pixels and the third color light sub-pixels on the pixel arrangement structure is not affected, thereby effectively extending the service life of the pixel arrangement structure.

### BRIEF DESCRIPTION OF DRAWINGS

FIG. 1 is a schematic diagram illustrating a pixel arrangement structure according to an embodiment of the present application.

FIG. 2 is a schematic diagram illustrating an arrangement structure of a first pixel group according to an embodiment of the present application.

FIG. 3 is a schematic diagram illustrating second color light sub-pixels and third color light sub-pixels of a first pixel group close to and parallel to corresponding side edges of a first color light sub-pixel according to an embodiment of the present application.

FIG. 4 is a schematic diagram illustrating second color light sub-pixels and third color light sub-pixels shared by adjacent pixel groups in a pixel arrangement structure are located on a same straight line according to an embodiment of the present application.

FIG. 5 is a schematic diagram illustrating a pixel arrangement structure according to another embodiment of the present application.

### DETAILED DESCRIPTION

In order to make the purposes, technical solutions and advantages of the present application clearer, the technical solutions of the present application are described clearly and completely in the following in combination with specific embodiments of the present application and corresponding drawings. Obviously, the described embodiments are only a part of the embodiments of the present application, but not all the embodiments. Based on the embodiments in the present application, all other embodiments obtained by those skilled in the art without creative efforts, shall fall within the protection scope of the present application.

The embodiments of the present application provide a pixel arrangement structure to solve a problem that the effective service life of the entire display is greatly shortened due to the decline of the blue light device existing in the prior art. The pixel arrangement structure provided according to the embodiments of the present application includes a plurality of pixel groups. The plurality of pixel groups are arranged in at least two rows and/or at least two columns, and two adjacent pixel groups of the plurality of pixel groups share a second color light sub-pixel and a third color light sub-pixel located between the two adjacent pixel groups. The technical solutions provided by the embodiments of the present application are described in detail below in combination with the accompanying drawings.

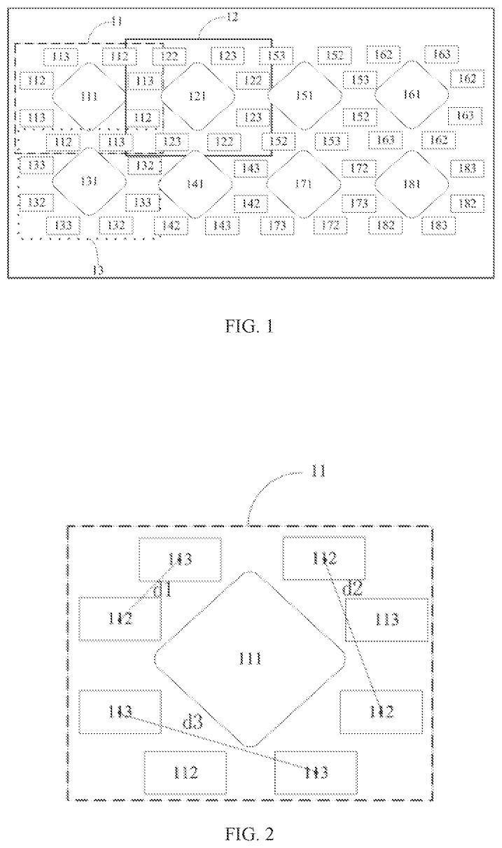

As shown in FIG. 1, the pixel arrangement structure provided by the embodiments of the present application includes a plurality of pixel groups, such as a first pixel group 11, a second pixel group 12, and a third pixel group 13 shown in FIG. 1. Each pixel group includes a first color light sub-pixel. For example, the first pixel group shown in FIG. 1 includes a first color light sub-pixel 111. The second pixel group includes a first color light sub-pixel 121. The third pixel group includes a first color light sub-pixel 131. The fourth pixel group includes a first color light sub-pixel 141. The fifth pixel group includes a first color light sub-pixel 151. The sixth pixel group includes a first color light sub-pixel 161. The seventh pixel group includes a first color light sub-pixel 171. The eighth pixel group includes a first color light sub-pixel 181, and the like.

Each pixel group further includes a plurality of second color light sub-pixels and a plurality of third color light sub-pixels alternately arranged around the first color light sub-pixel. The number of the plurality of second color light sub-pixels and the number of the plurality of third color light sub-pixels are at least two, and preferably three or more, respectively. For example, in the first pixel group, there are second color light sub-pixels 112 and third color light sub-pixels 113 alternately arranged around the first color light sub-pixel 111. In the second pixel group, there are second color light sub-pixels 122 and third color light sub-pixels 123 alternately arranged around the first color light sub-pixel 121. The first pixel group 11 and the second pixel group 12 share one second color light sub-pixel 112 and one third color light sub-pixel 113. In the third pixel group 13, there are second color light sub-pixels 132 and third color light sub-pixels 133 alternately arranged around the first color light sub-pixel 131. The first pixel group 11 and the third pixel group 13 share one second color light sub-pixel 112 and one third color light sub-pixel 113. In the fourth pixel group 14, there are second color light sub-pixels 142 and third color light sub-pixels 143 alternately arranged around the first color light sub-pixel 141.

The fourth pixel group 14 and the third pixel group 13 share one second color light sub-pixel 132 and one third color light sub-pixel 133. An arrangement relationship of the first color light sub-pixel 151, the second color light sub-pixel 152 and the third color light sub-pixel 153 in the fifth pixel group, an arrangement relationship of the first color light sub-pixel 161, the second color light sub-pixel 162 and the third color light sub-pixel 163 in the sixth pixel group, an arrangement relationship of the first color light sub-pixel 171, the second color light sub-pixel 172 and the third color light sub-pixel 173 in the seventh pixel group, and an arrangement relationship of the first color light sub-pixel 181, the second color light sub-pixel 182 and the third color light sub-pixel 183 in the eighth pixel group are the same as an arrangement relationship of the first color light sub-pixel, the second color light sub-pixel and the third color light sub-pixel in the first pixel group (the second pixel group or the third pixel group) described above. In addition, a case of two adjacent pixel groups of the fifth pixel group, the sixth pixel group, the seventh pixel group and the eighth pixel group sharing a second color light sub-pixel and a third color light sub-pixel is the same as a case of two adjacent pixel groups of the first pixel group 11, the second pixel group 12, the third pixel group 13 and the fourth pixel group 14 sharing a second color light sub-pixel and a third color light sub-pixel described above. The first pixel group 11, the second pixel group 12, the third pixel group 13 and the fourth pixel group 14 are arranged in at least two rows and/or at least two columns.

Two adjacent pixel groups share a second color light sub-pixel and a third color light sub-pixel located between the two adjacent pixel groups. The pixel structure may at least include pixel groups arranged in two rows and two columns, that is, the pixel structure at least includes the first pixel group 11, the second pixel group 12, the third pixel group 13 and the fourth pixel group 14 arranged in two rows and two columns as shown in FIG. 1. Two adjacent pixel groups in a horizontal direction or a vertical direction share the second color light sub-pixel and the third color light sub-pixel located between the two adjacent pixel groups. As shown in FIG. 1, the first pixel group 11 and the second pixel group 12 share one second color light sub-pixel 112 and one third color light sub-pixel 113; the first pixel group 11 and the third pixel group 13 share one second color light sub-pixel 112 and one third color light sub-pixel 113; the second pixel group 12 and the fourth pixel group 14 share one second color light sub-pixel 122 and one third color light sub-pixel 123; and the third pixel group 13 and the fourth pixel group 14 share one second color light sub-pixel 132 and one third color light sub-pixel 133. Therefore, this sharing method can significantly improve the pixel resolution. In addition, when a first color light sub-pixel has a problem or is damaged, a second color light sub-pixel and a third color light sub-pixel around the first color light sub-pixel can form a pixel with another first color light sub-pixel near the second color light sub-pixel and the third color light sub-pixel, thereby being lit up. For example, when the first color light sub-pixel 131 in the third pixel group 13 is damaged, the second color light sub-pixel 132 located on the right of the first color light sub-pixel 131 can form a pixel with the first color light sub-pixel 141 and the third color light sub-pixel 133, thereby effectively avoiding the technical problem that sub-pixels constituting a pixel unit with a first color light sub-pixel cannot be used normally due to the damage of the first color light sub-pixel.

In each pixel group, the second color light sub-pixels and the third color light sub-pixels, alternately arranged around the first color light sub-pixel, are evenly arranged at equal intervals. As shown in FIG. 2, taking the first pixel group 11 as an example, in the first pixel group 11, an interval between the second color light sub-pixel 112 and the third color light sub-pixel 113 alternately arranged around the first color light sub-pixel 111 is a certain value, that is, a distance between the second color light sub-pixel 112 and the third color light sub-pixel 113 adjacent to the second color light sub-pixel 112 may be a first distance d1; and/or, a distance between two adjacent second color light sub-pixels 112 is a second distance d2; and/or, a distance between two adjacent third color light sub-pixels 113 is a third distance d3. Whether the second distance d2 is the same as the third distance d3 can be determined according to actual needs, which is not specifically limited here.

An opening of the first color light sub-pixel is in a shape of polygon, and at least one second color light sub-pixel and at least one third color light sub-pixel are disposed on a same side of each side edge of the first color light sub-pixel. Preferably, the polygon is a regular polygon.

The opening of the first color light sub-pixel is in a shape of polygon, and the specific number of side edges of the polygon is not specifically limited herein. For example, the specific number is 3, that is, the first color light sub-pixel is in a shape of triangle; or, the specific number is 4, that is, the first color light sub-pixel is in a shape of quadrilateral; or, the polygon is another shape, which is not specifically limited herein. At least one second color light sub-pixel and at least one third color light sub-pixel are provided on the same side of each side edge of the first color light sub-pixel to form a pixel with the first color light sub-pixel. Further, a shape of the first color light sub-pixel is a regular polygon, such as a regular triangle, a regular quadrilateral, a regular pentagon, or the like.

Preferably, side edges, close to the first color light sub-pixel, of each of the plurality of second color light sub-pixels and each of the plurality of third color light sub-pixels in each pixel group are parallel to a corresponding side edge of the first color light sub-pixel.

Referring to FIG. 5, taking the first pixel group 11 as an example for explanation. In the first pixel group 11, side edges, near the first color light sub-pixel 111, of the second color light sub-pixel 112 and the third color light sub-pixel 113 located on the upper right side of the first color light sub-pixel 111 are parallel to an upper right side edge of the first color light sub-pixel 111. Side edges, near the first color light sub-pixel 111, of the second color light sub-pixel 112 and the third color light sub-pixel 113 located on the upper left side of the first color light sub-pixel 111 are parallel to an upper left side edge of the first color light sub-pixel 111. Side edges, near the first color light sub-pixel 111, of the second color light sub-pixel 112 and the third color light sub-pixel 113 located on the lower left side of the first color light sub-pixel 111 are parallel to a lower left side edge of the first color light sub-pixel 111. Side edges, near the first color light sub-pixel 111, of the second color light sub-pixel 112 and the third color light sub-pixel 113 located on the lower right side of the first color light sub-pixel 111 are parallel to a lower right side edge of the first color light sub-pixel 111.

When the second color light sub-pixel and the third color light sub-pixel are in a shape of rectangle, in each pixel group, a center connection line of a second color light sub-pixel and a third color light sub-pixel corresponding to a same side edge of the first color light sub-pixel is parallel to the same side edge of the first color light sub-pixel.

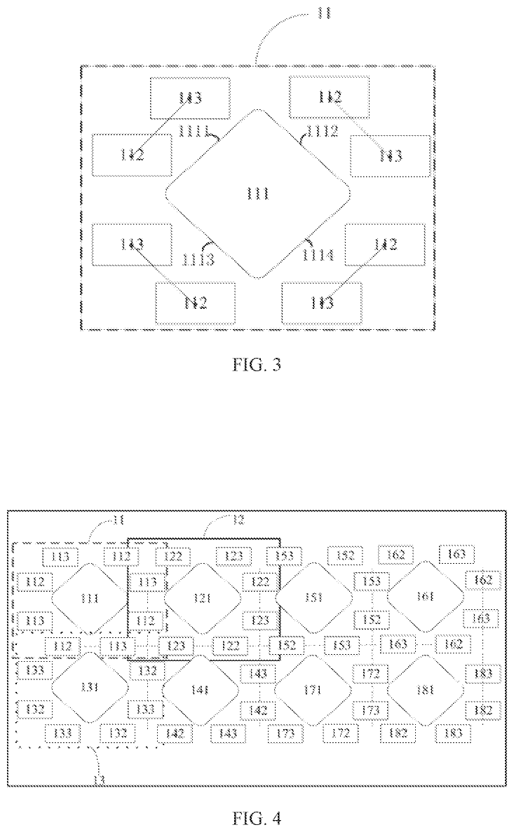

Referring to FIG. 3, taking the first pixel group 11 as an example for explanation. In the first pixel group 11, a connection line connecting center points of the second color light sub-pixel 112 and the third color light sub-pixel 113 near the upper left side of the first pixel group 11 is parallel to an upper left side edge 1111 of the first color light sub-pixel 111. A connection line connecting center points of the second color light sub-pixel 112 and the third color light sub-pixel 113 near the upper right side of the first pixel group 11 is parallel to an upper right side edge 1112 of the first color light sub-pixel 111. A connection line connecting center points of the second color light sub-pixel 112 and the third color light sub-pixel 113 near the lower left side of the first pixel group 11 is parallel to a lower left side edge 1113 of the first color light sub-pixel 111. A connection line connecting center points of the second color light sub-pixel 112 and the third color light sub-pixel 113 near the lower right side of the first pixel group 11 is parallel to a lower right side edge 1114 of the first color light sub-pixel 111.

Projections of a plurality of the first color light sub-pixels along a row direction or a column direction are overlapped.

As shown in FIG. 1, in the row direction, projections of the first color light sub-pixels of the pixel groups arranged horizontally in the pixel structure are overlapped, that is, in the row direction, the projections of the first color light sub-pixel 111 of the first pixel group 11, the first color light sub-pixel 121 of the second pixel group 12, the first color light sub-pixel 151 of the fifth pixel group 15 and the first color light sub-pixel 161 of the sixth pixel group 16 are overlapped; and/or, in the column direction, projections of the first color light sub-pixels of the pixel groups arranged vertically in the pixel structure are overlapped, that is, in the column direction, the projections of the first color light sub-pixel 111 of the first pixel group 11 and the first color light sub-pixel 131 of the third pixel group 13 are overlapped; and in the column direction, projections of the first color light sub-pixels 121 of the second pixel group 12 and the first color light sub-pixels 141 of the fourth pixel group 14 are overlapped. Such setting improves a regularity of an arrangement of sub-pixels in a display while ensuring the effective service life of the display, thereby effectively ensuring a uniformity of pixel arrangement in the display.

An opening of the first color light sub-pixel is in a shape of quadrilateral, the second color light sub-pixels and the third color light sub-pixels shared by the pixel groups located in two adjacent rows are located on a same straight line, and/or the second color light sub-pixels and the third color light sub-pixels shared by the pixel groups located in two adjacent columns are located on a same straight line.

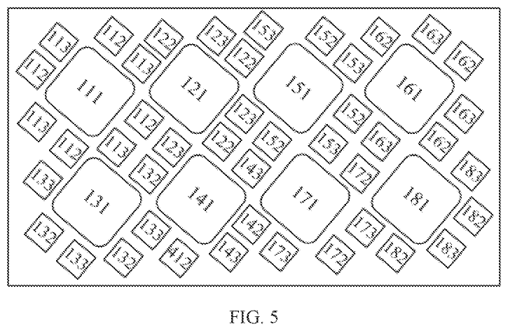

In the embodiments of the present application, the second color light sub-pixels and the third color light sub-pixels shared by at least two pixel groups in a same row and at least two pixel groups in an adjacent row are located on a same straight line; and/or the second color light sub-pixels and the third color light sub-pixels shared by at least two pixel groups in a same column and at least two pixel groups in an adjacent column are located on a same straight line. As shown in FIG. 4, the second color light sub-pixel 112 and the third color light sub-pixel 113 shared by the first pixel group and the third pixel group and the second color light sub-pixel 122 and the third color light sub-pixel 123 shared by the second pixel group and fourth pixel group are located on the same straight line. The first pixel group and the second pixel group are pixel groups in the same row, and the third pixel group and the fourth pixel group are pixel groups in the adjacent row. And/or, the second color light sub-pixel 112 and the third color light sub-pixel 113 shared by the first pixel group and the second pixel group and the second color light sub-pixel 132 and the third color light sub-pixel 133 shared by the third pixel group and the fourth pixel group are located on the same straight line. The first pixel group and the third pixel group are pixel groups in the same column, and the second pixel group and the fourth pixel group are pixel groups in the adjacent column. In this way, a neatness of an arrangement of pixel groups in the pixel arrangement structure is effectively improved, which is convenient for later maintenance. It is pointed out here that the arrangement of the second color light sub-pixels and the third color light sub-pixels shared by other pixel groups can also be arranged in this manner. The opening described in the present application refers to a light exit of a sub-pixel.

In the embodiments of the present application, the first color light sub-pixel is a blue light sub-pixel, the second color light sub-pixel and the third color light sub-pixel are a red light sub-pixel and a green light sub-pixel. Preferably, an opening area of the first color light sub-pixel is larger than opening areas of the second color light sub-pixel and the third color light sub-pixels. Each of the first color light sub-pixel 111, the first color light sub-pixel 121, the first color light sub-pixel 131, the first color light sub-pixel 141, the first color light sub-pixel 151, the first color light sub-pixel 161, the first color light sub-pixel 171 and the first color light sub-pixel 181 is a blue light sub-pixel. As a specific embodiment, each of the second color light sub-pixel 112, the second color light sub-pixel 122, the second color light sub-pixel 132, the second color light sub-pixel 142, the second color light sub-pixel 152, the second color light sub-pixel 162, the second color light sub-pixel 172 and the second color light sub-pixel 182 is a red light sub-pixel; and each of the third color light sub-pixel 113, the third color light sub-pixel 123, the third color light sub-pixel 133, the third color light sub-pixel 143, the third color light sub-pixel 153, the third color light sub-pixel 163, the third color light sub-pixel 173 and the third color light sub-pixel 183 is a green light sub-pixel. The red light sub-pixel and the green light sub-pixel are also interchangeable. In the embodiments of the present application, it is preferable that the opening area of the blue light sub-pixel is larger than the opening area of the green light sub-pixel and the opening area of the red light sub-pixel, so that more red light sub-pixels and green light sub-pixels can be arranged around the blue sub-pixel, thereby effectively improving a utilization rate of the blue light sub-pixel.

Each of the first color light sub-pixels can be combined with a second color light sub-pixel and a third color light sub-pixel adjacently arranged in the same pixel group to form a pixel unit. Taking the first pixel group 11 as an example, the first color light sub-pixel 111 and the second color light sub-pixel 112 and the third color light sub-pixel 113 located on an upper left side of the first color light sub-pixel 111 are combined into a pixel unit. In addition, each of the first color light sub-pixels can be combined with a second color light sub-pixel and a third color light sub-pixel spaced apart in the same pixel group to form a pixel unit. Taking the first pixel group 11 as an example, the first color light sub-pixel 111, the second color light sub-pixel 112 located on a left side of the first color light sub-pixel 111, and the third color light sub-pixel 113 located on a right side of the first color light sub-pixel 111 are combined into a pixel unit. Of course, each pixel unit is not limited to include three sub-pixels, it can be multiple, which belongs to a protection scope of the present application as long as each pixel unit includes the first color light sub-pixel, the second color light sub-pixel and the third color light sub-pixel. The present application preferably forms a pixel unit in a form of using a first color light sub-pixel, a second color light sub-pixel and a third color light sub-pixel, wherein the second color light sub-pixel and the third color light sub-pixel are arranged along the same side of the first color light sub-pixel.

In the embodiment of the present application, an opening of the first color light sub-pixel is in a shape of polygon, an opening of the second color light sub-pixel is in a shape of diamond or rectangle, and an opening of the third color light sub-pixel is in a shape of diamond or rectangle. Preferably, the polygon is a diamond or an equilateral triangle. Specifically, the opening of the first color light sub-pixel is in a shape of polygon, such as a trilateral (triangle), a quadrilateral, etc. In a specific embodiment, the opening of the first color light sub-pixel is in a shape of regular triangle or diamond. As shown in FIG. 5, an example is shown in this figure that the opening of the first color light sub-pixel is only in a shape of diamond. It is pointed out here that each corner of the regular triangle or diamond is a rounded corner. In addition, the regular triangle or diamond here may be a regular triangle or diamond within a range allowed in the field. In a specific embodiment, the shape of the opening of the first color light sub-pixel 111 of the first pixel group 11, the shape of the opening of the first color light sub-pixel 121 of the second pixel group 12, the shape of the opening of the first color light sub-pixel 131 of the third pixel group 13, the shape of the opening of the first color light sub-pixel 141 of the fourth pixel group 14, the shape of the opening of the first color light sub-pixel 151 of the fifth pixel group 15, the shape of the opening of the first color light sub-pixel 161 of the sixth pixel group 16, the shape of the opening of the first color light sub-pixel 171 of the seventh pixel group 17, and the shape of the opening of the first color light sub-pixel 181 of the eighth pixel group 18 are the same, all of them can be regular triangle or diamond, and the figure only shows the diamond as an example.

Referring to FIG. 5, taking the first pixel group 11 as an example for explanation. In the first pixel group 11, a connection line connecting center points of the second color light sub-pixel 112 and the third color light sub-pixel 113 near the upper left side of the first pixel group 11 is parallel to an upper left side edge of the first color light sub-pixel 111. A connection line connecting center points of the second color light sub-pixel 112 and the third color light sub-pixel 113 near the upper right side of the first pixel group 11 is parallel to an upper right side edge of the first color light sub-pixel 111. A connection line connecting center points of the second color light sub-pixel 112 and the third color light sub-pixel 113 near the lower left side of the first pixel group 11 is parallel to a lower left side edge of the first color light sub-pixel 111. A connection line connecting center points of the second color light sub-pixel 112 and the third color light sub-pixel 113 near the lower right side of the first pixel group 11 is parallel to a lower right side edge of the first color light sub-pixel 111.

The embodiments of the present application further disclose a display device including the pixel arrangement structure according to any one of the above embodiments.

The embodiments of the present application further disclose a display panel including the pixel arrangement structure according to any one of the above embodiments.

In summary, according to the technical solutions of the present application, a pixel arrangement structure including a plurality of pixel groups is constructed. Each pixel group includes a first color light sub-pixel, a plurality of second color light sub-pixels and a plurality of third color light sub-pixels, and the plurality of second color light sub-pixels and the plurality of third color light sub-pixels are alternately arranged around the first color light sub-pixel, such that multiple second color light sub-pixels and multiple third color light sub-pixels share a first color light sub-pixel. Each second color light sub-pixel and each third color light sub-pixel are shared by two adjacent pixel groups. Therefore, even if some of the first color light sub-pixels are damaged, the use of the second color light sub-pixels and the third color light sub-pixels on the pixel arrangement structure is not affected, thereby effectively extending the service life of the pixel arrangement structure. When the number of pixel groups included in the pixel arrangement structure is large enough, adjacent first color light sub-pixels can be used alternately, thus effectively avoiding a technical problem that a display screen is biased toward yellow due to a damage of part of the first color light sub-pixels, which effectively extends the service life of the display.

The above descriptions are only examples of the present application, and are not intended to limit the present application. For those skilled in the art, the present application may have various modifications and changes. Any modification, equivalent replacement, improvement, etc. made within the spirit and principles of the present application shall be included in the scope of the claims of the present application.

What is claimed is:

1. A pixel arrangement structure, comprising:
a plurality of pixel groups, wherein each of the plurality of pixel groups comprises a first color light sub-pixel, a plurality of second color light sub-pixels and a plurality of third color light sub-pixels, and the plurality of second color light sub-pixels and the plurality of third color light sub-pixels are alternately arranged around the first color light sub-pixel;
wherein the plurality of pixel groups are arranged in at least two rows and/or at least two columns, and two adjacent pixel groups of the plurality of pixel groups share a second color light sub-pixel and a third color light sub-pixel located between the two adjacent pixel groups.

2. The pixel arrangement structure according to claim 1, wherein the number of the plurality of second color light sub-pixels and the number of the plurality of third color light sub-pixels are at least two, respectively.

3. The pixel arrangement structure according to claim 1, wherein the plurality of pixel groups comprises a first pixel group, a second pixel group, a third pixel group and a fourth pixel group arranged in two rows and two columns, the first pixel group and the second pixel group are arranged in a row, the third pixel group and the fourth pixel group are arranged in another row, and when a first color light sub-pixel in the third pixel group is damaged, a second color light sub-pixel and a third color light sub-pixel located between the third pixel group and the fourth pixel group form a pixel unit with a first color light sub-pixel in the fourth pixel group.

4. The pixel arrangement structure according to claim 1, wherein the plurality of second color light sub-pixels and the plurality of third color light sub-pixels alternately arranged around the first color light sub-pixel, are evenly arranged at equal intervals.

5. The pixel arrangement structure according to claim 4, wherein a distance between a second color light sub-pixel of the plurality of second color light sub-pixels and a third color light sub-pixel adjacent to the second color light sub-pixel is a first distance, a distance between two adjacent second color light sub-pixels of the plurality of second color light sub-pixels is a second distance, and a distance between two adjacent third color light sub-pixels of the plurality of third color light sub-pixels is a third distance.

6. The pixel arrangement structure according to claim 5, wherein the third distance is equal to the second distance or not equal to the second distance.

7. The pixel arrangement structure according to claim 1, wherein an opening of the first color light sub-pixel is in a shape of polygon, and at least one of the plurality of second color light sub-pixels and at least one of the plurality of third color light sub-pixels are disposed on a same side of each side edge of the first color light sub-pixel.

8. The pixel arrangement structure according to claim 7, wherein the polygon is a regular polygon.

9. The pixel arrangement structure according to claim 1, wherein side edges, close to the first color light sub-pixel, of each of the plurality of second color light sub-pixels and each of the plurality of third color light sub-pixels in each of the plurality of pixel groups are parallel to a corresponding side edge of the first color light sub-pixel.

10. The pixel arrangement structure according to claim 9, wherein the first color light sub-pixel forms a pixel unit with a second color light sub-pixel and a third color light sub-pixel, and the second color light sub-pixel and the third color light sub-pixel are arranged along the same side of the first color light sub-pixel.

11. The pixel arrangement structure according to claim 10, wherein the number of color light sub-pixels included in the pixel unit is greater than or equal to 3.

12. The pixel arrangement structure according to claim 1, wherein in each of the plurality of pixel groups, the first color light sub-pixel comprises a first side edge, and a center connection line of a second color light sub-pixel and a third color light sub-pixel corresponding to the first side edge of the first color light sub-pixel is parallel to the first side edge of the first color light sub-pixel.

13. The pixel arrangement structure according to claim 1, wherein projections of a plurality of the first color light sub-pixels along a row direction or a column direction are overlapped.

14. The pixel arrangement structure according to claim 1, wherein an opening of the first color light sub-pixel is in a shape of quadrilateral, the second color light sub-pixels and the third color light sub-pixels shared by two adjacent rows of the pixel groups are located on a same straight line, and/or the second color light sub-pixels and the third color light sub-pixels shared by two adjacent columns of the pixel groups are located on a same straight line.

15. The pixel arrangement structure according to claim 1, wherein the first color light sub-pixel is a blue light sub-pixel, each of the plurality of second color light sub-pixels and each of the plurality of third color light sub-pixels are a red light sub-pixel and a green light sub-pixel.

16. The pixel arrangement structure according to claim 15, wherein an opening area of the first color light sub-pixel is larger than that of each of the plurality of second color light sub-pixels and that of each of the plurality of third color light sub-pixels.

17. The pixel arrangement structure according to claim 1, wherein an opening of the first color light sub-pixel is in a shape of polygon, an opening of each of the plurality of second color light sub-pixels is in a shape of diamond or rectangle, and an opening of each of the plurality of third color light sub-pixels is in a shape of diamond or rectangle.

18. The pixel arrangement structure according to claim 17, wherein the polygon of the opening of the first color light sub-pixel is a diamond or an equilateral triangle.

19. A display panel, comprising the pixel arrangement structure according to claim 1.

20. A display device, comprising the display panel according to claim 19.
